(19) United States
(12) Patent Application Publication
(10) Pub. No.: US 2025/0393376 A1
(43) Pub. Date: Dec. 25, 2025

(54) DISPLAY APPARATUS

(71) Applicant: Samsung Display Co., Ltd., Yongin-si (KR)

(72) Inventors: Eonjoo Lee, Yongin-si (KR); Donguk Kim, Yongin-si (KR); Hyunho Kim, Yongin-si (KR); Donghwan Shim, Yongin-si (KR); Hyeonbum Lee, Yongin-si (KR); Hoongi Lee, Yongin-si (KR)

(21) Appl. No.: 19/242,818

(22) Filed: Jun. 18, 2025

(30) Foreign Application Priority Data
Jun. 19, 2024 (KR) 10-2024-0079791

(51) Int. Cl. H10H 29/85; G06F 3/044; H10H 29/37

(52) U.S. Cl. CPC H10H 29/8517; G06F 3/044; H10H 29/37

(57) ABSTRACT

A display apparatus is disclosed. The display apparatus may include a substrate, a display element layer on the substrate, which may include a plurality of light-emitting devices and a lower opening to define respective emission areas of the plurality of light-emitting devices, an input detection layer on the display element layer, and a light control layer on the input detection layer, wherein the light control layer may include a first light-blocking layer including a middle opening that is to at least partially overlap the lower opening, a color filter layer to fill the middle opening, which may be on the first light-blocking layer, and a second light-blocking layer on the color filter layer, which may include an upper opening that is to at least partially overlap the middle opening, and the first light-blocking layer may include a valley pattern to overlap a bank layer.

### CROSS-REFERENCE TO RELATED APPLICATION

The present application claims priority to and the benefit of Korean Patent Application No. 10-2024-0079791, filed on Jun. 19, 2024, in the Korean Intellectual Property Office, the entire disclosure of which is incorporated herein by reference.

### BACKGROUND

### 1. Field

One or more embodiments of the present disclosure relate to a structure of a display apparatus.

### 2. Description of the Related Art

A display apparatus visually displays data. The display apparatus may be used as a display for a relatively small electrical product, such as a mobile phone, and may also be used as a display for a relatively large electrical product, such as a television.

The display apparatus includes a plurality of pixels that receive electrical signals and emit light to display an image to the outside. Each pixel includes a display device, and, for example, in an organic light emitting display apparatus, each pixel includes an organic light emitting diode (OLED) as a display device.

### SUMMARY

One or more aspects of embodiments of the present disclosure are directed toward a display apparatus having improved or enhanced display quality. However, these embodiments are examples, and embodiments of the present disclosure are not limited thereto.

Additional aspects of embodiments will be set forth in part in the description which follows and, in part, will be apparent from the description, or may be learned by practice of the presented embodiments of the disclosure.

According to one or more embodiments, a display apparatus includes a substrate, a display element layer on the substrate, wherein the display element layer includes a plurality of light-emitting devices and a bank layer comprising a lower opening to define respective emission areas of the plurality of light-emitting devices, an input detection layer on the display element layer, and a light control layer on the input detection layer, wherein the light control layer includes a first light-blocking layer including a middle opening that is to at least partially overlap the lower opening, a color filter layer to fill the middle opening, wherein the color filter layer is on the first light-blocking layer, and a second light-blocking layer on the color filter layer, wherein the second light-blocking layer includes an upper opening that is to at least partially overlap the middle opening, and the first light-blocking layer includes a valley pattern to overlap the bank layer.

The input detection layer may include a touch insulating layer (e.g., a layer of material that provides insulation, for example, designed to prevent or reduce the transfer of heat or electricity if (e.g., when) touched) on the display element layer, and a conductive layer (e.g., an electrically conductive layer) on the touch insulating layer, and the valley pattern may be to expose therethrough an upper surface of the conductive layer.

The first light-blocking layer may be to cover an end of the conductive layer.

A planar width of the valley pattern may be less than a planar width of the conductive layer.

A plurality of light-emitting devices may include a first light-emitting device and a second light-emitting device that are to emit light of different colors and are adjacent to each other, and the color filter layer may include a first color filter corresponding to the first light-emitting device and a second color filter corresponding to the second light-emitting device.

The first color filter and the second color filter may be to overlap each other at least partially in a plane within the valley pattern.

The valley pattern may be filled with the color filter layer.

The upper surface of the conductive layer, exposed by the valley pattern, may be in direct contact with the color filter layer.

The first color filter and the second color filter may be spaced and/or apart (e.g., spaced apart or separated) from each other on a plane within the valley pattern.

The second light-blocking layer may be between the first color filter and the second color filter, which are spaced and/or apart (e.g., spaced apart or separated) from each other.

The valley pattern may be filled with the color filter layer and the second light-blocking layer.

The upper surface of the conductive layer, exposed by the valley pattern, may be in direct contact with the color filter layer and the second light-blocking layer.

The input detection layer may include a touch insulating layer (e.g., a layer of material that provides insulation, for example, designed to prevent or reduce the transfer of heat or electricity if (e.g., when) touched) on the display element layer, a conductive layer on the touch insulating layer, and a clad layer on the conductive layer, and the valley pattern may be to expose therethrough an upper surface of the clad layer.

The first light-blocking layer may be spaced and/or apart (e.g., spaced apart or separated) from the conductive layer on a plane within the valley pattern.

A planar width of the valley pattern may be greater than a planar width of the conductive layer.

The upper surface of the clad layer may be in direct contact with the color filter layer within the valley pattern.

The display apparatus may further include an encapsulation layer between the display element layer and the input detection layer.

According to one or more embodiments, a display apparatus includes a substrate, a display element layer on the substrate, wherein the display element layer includes a first light-emitting device and a second light-emitting device that are to emit light of different colors and are located adjacent to each other, a first light-blocking layer on the display element layer, wherein the first light-blocking layer includes a first opening corresponding to the first light-emitting device and a second opening corresponding to the second light-emitting device, a color filter layer on the first light-blocking layer, wherein the color filter layer includes a first color filter to fill the first opening and a second color filter to fill the second opening, and a second light-blocking layer on the color filter layer, wherein the first light-blocking layer further includes a valley pattern between the first opening and the second opening.

The display apparatus may further include an input detection layer between the display element layer and the first light-blocking layer, wherein the input detection layer may include a touch insulating layer (e.g., a layer of material that provides insulation, for example, designed to prevent or reduce the transfer of heat or electricity if (e.g., when) touched) on the display element layer and a conductive layer on the touch insulating layer.

The valley pattern may be to expose therethrough an upper surface of the conductive layer, and the first light-blocking layer may be to cover an end of the conductive layer.

A planar width of the valley pattern may be less than a planar width of the conductive layer.

The first color filter and the second color filter may be to overlap each other at least partially in a plane within the valley pattern.

The first color filter and the second color filter may be spaced and/or apart (e.g., spaced apart or separated) from each other on a plane within the valley pattern.

The input detection layer may further include a clad layer on the conductive layer, and the valley pattern may be to expose therethrough an upper surface of the clad layer.

A planar width of the valley pattern may be greater than a planar width of the conductive layer.

According to one or more embodiments, an electronic device including a display apparatus includes a display element layer on the substrate, wherein the display element layer comprises a plurality of light-emitting devices and a bank layer comprising a lower opening to define respective emission areas of the plurality of light-emitting devices, an input detection layer on the display element layer, and a light control layer on the input detection layer, wherein the light control layer comprises a first light-blocking layer comprising a middle opening that is to at least partially overlap the lower opening, a color filter layer to fill the middle opening, wherein the color filter layer is on the first light-blocking layer; and a second light-blocking layer on the color filter layer, wherein the second light-blocking layer comprises an upper opening that is to at least partially overlap the middle opening, and the first light-blocking layer comprises a valley pattern to overlap the bank layer.

The electronic device may further comprise, a display module, a processor, a power module, and a memory, wherein the display apparatus includes one of the display module, the processor, the power module, or the memory.

### BRIEF DESCRIPTION OF THE DRAWINGS

The above and other aspects and features of certain embodiments of the present disclosure will be more apparent from the following description taken in conjunction with the accompanying drawings, in which:

FIG. 1 is a schematic perspective view illustrating a display apparatus according to one or more embodiments;

FIG. 2 is an equivalent circuit diagram illustrating a display element provided in one subpixel and a subpixel connected to the display element in a display apparatus according to one or more embodiments;

FIG. 3 is a schematic cross-sectional view illustrating a display apparatus according to one or more embodiments;

FIG. 4 is a schematic plan view illustrating an input detection layer of a display apparatus according to one or more embodiments;

FIG. 5 is a schematic cross-sectional view illustrating a portion of a display apparatus according to one or more embodiments;

FIG. 6 is a schematic cross-sectional view illustrating a portion of a display apparatus according to one or more embodiments; and

FIG. 7 is a schematic cross-sectional view illustrating a portion of a display apparatus according to one or more embodiments.

FIG. 8 is a block diagram of an electronic apparatus according to one or more embodiments.

FIG. 9 is a schematic diagrams of electronic apparatuses according to various embodiments.

### DETAILED DESCRIPTION

Reference will be made in more detail to one or more embodiments, examples of which are illustrated in the accompanying drawings, wherein like reference numerals refer to like elements throughout. In this regard, the subject matter of the present disclosure may be embodied in different forms and should not be construed as being limited to one or more embodiments set forth herein. Rather, these embodiments are provided as examples, by referring to the figures, to explain the aspects and features of the present disclosure to those skilled in the art.

As used herein, the term “and/or” includes any and all combinations of one or more of the associated listed items. Throughout the present disclosure, the expression “at least one of a, b, or c” indicates only a, only b, only c, both a and b, both a and c, both b and c, all of a, b, and c, or variations thereof.

As the present disclosure allows for one or more suitable changes and embodiments, certain embodiments will be illustrated in the accompanying drawings and described in more detail in the written description. The accompanying drawings to illustrate one or more embodiments are referred to gain or provide a sufficient and better understanding of embodiments, the aspects and features of the present disclosure, and the objectives accomplished by the implementation of the present disclosure. However, the disclosure is not limited to the disclosed embodiments, but may be implemented in one or more different forms.

Hereinafter, the subject matter of the present disclosure will be described in more detail with reference to the accompanying drawings. The same reference numerals in the drawings denote like elements, and a repeated illustration thereof may not be provided.

In one or more embodiments, terms, such as “first,” “second,” and/or the like, are used to distinguish one component from another component without a limiting meaning.

In one or more embodiments, the singular expressions in the present disclosure include the plural expressions unless clearly specified otherwise in context.

In one or more embodiments, terms, such as “include” or “have,” refer to that the characteristics or elements described in the specification exist and do not preclude the possibility that one or more other characteristics or elements may be added.

In one or more embodiments, if (e.g., when) a portion, such as a film, a region, a component, and/or the like, is referred to as being “above” or “on” other portions, this includes that the portion may be “directly on” other portions as well as that other films, other regions, other components, and/or the like may be therebetween. In contrast, if (e.g., when) a portion is referred to as being “directly on” other portions, there are no intervening portions present.

For convenience of illustration, in the drawings, the size of components may be exaggerated or reduced. For example, sizes and thicknesses of the elements illustrated in the drawings are for convenience of description, and thus embodiments of the present disclosure are not necessarily limited thereto.

Unless otherwise stated or implied, a certain process order may be performed substantially differently from the described order. For example, two processes described in succession may be performed substantially simultaneously or may be performed in an order opposite to the order described.

In one or more embodiments, if (e.g., when) films, regions, components, and/or the like are connected, this refers to that films, regions, components, and/or the like may be directly connected and/or that other films, regions, components, and/or the like may be therebetween. For example, if (e.g., when) a film, a region, a component, and/or the like is electrically connected in the present disclosure, this refers to that the film, the region, the component, and/or the like may be directly electrically connected and/or indirectly electrically connected in which another film, region, component, and/or the like may be therebetween. In contrast, if (e.g., when) films, regions, components, and/or the like are referred to as being “directly” electrically connected to each other, there are no intervening films, regions, components, and/or the like present.

The x-axis, y-axis, and z-axis are not limited to the three axes of the Cartesian coordinate system, and may be interpreted in a broad sense including them. For example, the x-axis, y-axis, and z-axis may be substantially orthogonal to each other, but may refer to substantially different directions that are not substantially orthogonal to each other.

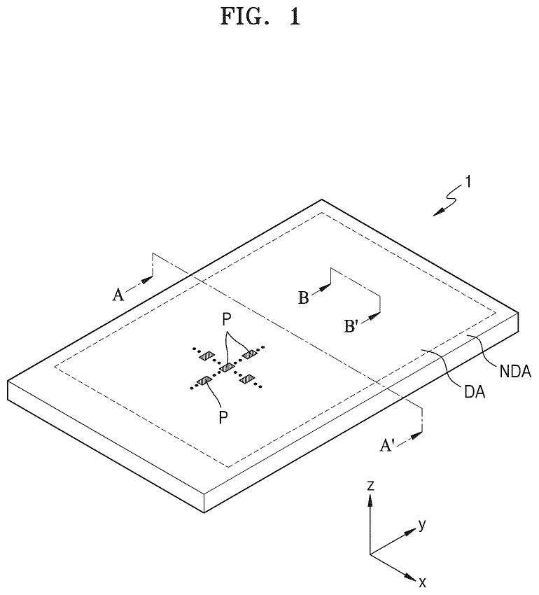

FIG. 1 is a schematic perspective view illustrating a display apparatus according to one or more embodiments.

According to one or more embodiments, a display apparatus 1 may be an apparatus that displays a moving image and/or a still image and may be used as a display screen of one or more suitable products, such as a television, a laptop, a monitor, a billboard, and/or an Internet of Things (IoT) as well as a portable device, such as a mobile phone, a smartphone, a tablet personal computer (PC), a mobile communication terminal, an electronic notebook, an electronic book, a portable multimedia player (PMP), a navigation device, and/or an ultra-mobile PC (UMPC).

According to one or more embodiments, the display apparatus 1 may be used in a wearable apparatus, such as a smart watch, a watch phone, a glasses-type or -kind display, and/or a head mounted display (HMD). According to one or more embodiments, the display apparatus 1 may be used as a dashboard of a car, a center information display (CID) on a center fascia and/or a dashboard of a car, a room mirror display replacing a side mirror of a car, and/or a display on a rear surface of a front seat as entertainment for backseat passengers in a car. For convenience of illustration, FIG. 1 illustrates the display apparatus 1 being used as a smart phone.

Referring to FIG. 1, the display apparatus 1 according to one or more embodiments may include a display area DA and/or a non-display area NDA outside the display area DA. In FIG. 1, the display area DA is illustrated as having a roughly rectangular (e.g., substantially rectangular) shape, but embodiments of the present disclosure are not limited thereto. The display area DA may be provided in one or more suitable shapes, such as a circle (e.g., substantially a circle), an oval (e.g., substantially an oval), or a polygon (e.g., substantially a polygon).

The display area DA may be a portion that displays an image, and a plurality of subpixels P may be in the display area DA. Each subpixel P may include a light-emitting device, such as a light-emitting diode LED. Each subpixel P may be to emit light of, for example, red, green, blue, or white.

The display area DA may provide a certain image through light emitted from the subpixels P. In one or more embodiments, the subpixel P may be defined as an emission area that may be to emit light of any one selected from among red, green, blue, or white colors, as described in one or more embodiments.

The non-display area NDA may be an area in which the subpixels P are not provided and/or may be an area that does not provide an image. A printed circuit board including a power supply wiring and a driving circuit to drive the subpixels P and/or a terminal unit to which a driver integrated circuit (IC) is connected may be in the non-display area NDA.

Hereinafter, an organic light emitting display apparatus will be described as an example of a display apparatus according to one or more embodiments. However, the display apparatus according to one or more embodiments is not limited thereto. For example, the display according to one or more embodiments may be an inorganic light emitting display apparatus (or inorganic electroluminescent (EL) apparatus) or a display apparatus, such as a quantum dot light emitting display apparatus. For example, an emission layer included in a light-emitting device provided in the display apparatus may include an organic material and/or an inorganic material. Quantum dots may be on a path of light emitted from the emission layer.

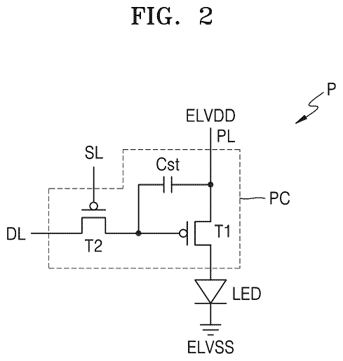

FIG. 2 is an equivalent circuit diagram illustrating a display element provided in one subpixel and/or a subpixel connected to the display element in a display apparatus according to one or more embodiments.

Referring to FIG. 2, a light emitting diode LED, which is a display element, may be connected to a subpixel circuit PC. The subpixel circuit PC may include a first transistor T1, a second transistor T2, and a storage capacitor Cst. The light emitting diode LED may be to emit red, green, or blue light, for example, or may be to emit red, green, blue, or white light.

The second transistor T2 may be a switching transistor, connected to a scan line SL and a data line DL, and may be to transmit a data voltage input from a data line DL to the first transistor T1 according to a switching voltage input from the scan line SL. The storage capacitor Cst may be connected to the second transistor T2 and a driving voltage line PL and may be to store a voltage corresponding to a difference between a voltage received from the second transistor T2 and a first power supply voltage ELVDD supplied to the driving voltage line PL.

The first transistor T1 may be a driving transistor, connected to the driving voltage line PL and the storage capacitor Cst, and may be to control a driving current flowing through the light emitting diode LED from the driving voltage line PL in response to a voltage value stored in the storage capacitor Cst. The light emitting diode LED may be to emit light having a set or certain brightness depending on the driving current. A first electrode (e.g., anode) of the light emitting diode LED may be connected to the subpixel circuit PC, and a second electrode (e.g., cathode) of the light emitting diode LED may be to receive a second power supply voltage ELVSS.

Although FIG. 2 illustrates that the subpixel circuit PC includes two transistors and one storage capacitor according to one or more embodiments, the number of transistors and/or the number of storage capacitors may vary depending on a design of the subpixel circuit PC.

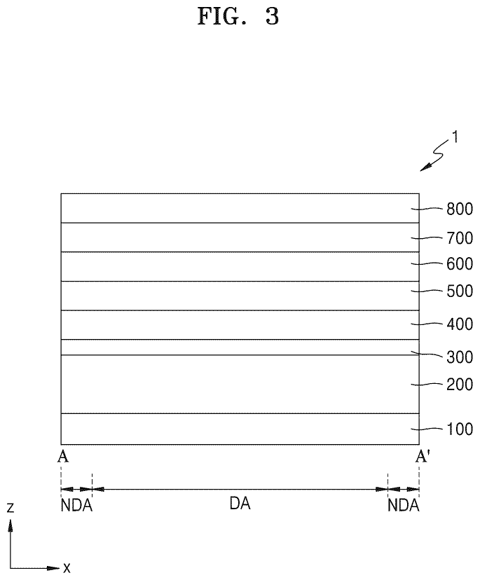

FIG. 3 is a schematic cross-sectional view illustrating a display apparatus according to one or more embodiments. For example, FIG. 3 is a cross-sectional view taken along a line A-A′ of FIG. 1.

Referring to FIG. 3, the display apparatus 1 according to one or more embodiments may include a substrate 100, a display element layer 200, a low reflective layer 300 (e.g., a layer that reflects substantially little light and/or other types or kinds of radiation), an encapsulation layer 400, an input detection layer 500, a light control layer 600, an adhesive layer 700, and a protective layer 800.

The substrate 100 may include glass and/or a polymer resin. For example, the polymer resin may include polyethersulfone, polyacrylate, polyether imide, polyethylene naphthalate, polyethylene terephthalate, polyphenylene sulfide, polyarylate, polyimide, polycarbonate, and/or cellulose acetate propionate. The substrate 100 including the polymer resin may have flexible (e.g., substantially flexible), rollable (e.g., substantially rollable), and/or bendable (e.g., substantially bendable) characteristics. The substrate 100 may have a multilayer structure including a layer containing the polymer resin and/or an inorganic layer.

The display element layer 200 may include an organic light-emitting diode as a display element, a thin (e.g., substantially thin) film transistor electrically connected to the organic light-emitting diode, and insulating (e.g., electrically insulating) layers therebetween.

The low reflective layer 300 may be on the display element layer 200, and the encapsulation layer 400 may be on the low reflective layer 300. For example, the display element layer 200 and/or the low reflective layer 300 may be sealed with the encapsulation layer 400. The encapsulating layer 400 may include at least one inorganic film layer and/or at least one organic film layer.

The input detection layer 500 may be on the encapsulation layer 400. The input detection layer 500 may be to detect an external input, such as a touch of an object, such as a finger and/or a stylus pen, and thus the display apparatus 1 may be to obtain coordinate information corresponding to a touch location. The input detection layer 500 may include a touch electrode and/or trace lines connected to the touch electrode. The input detection layer 500 may be to detect an external input by using a mutual cap method and/or a self-cap method.

The light control layer 600 may be on the input detection layer 500. The light control layer 600 may include a color filter, as described in more detail herein, and the color filter may have a color corresponding to light emitted from an emission layer below each color filter. The light control layer 600 may improve or enhance reflection characteristics by including not only the color filter but also a light-blocking layer, as described in more detail herein. In one or more embodiments, the light control layer 600 may include an overcoat layer to planarize upper surfaces of a plurality of color filters.

The adhesive layer 700 may be on the light control layer 600, and the protective layer 800 may be on the adhesive layer 700. The adhesive layer 700 may include, for example, a silicon-based adhesive material and/or a urethane-based adhesive material. The protective layer 800 may include a plastic film, such as polyethylene terephthalate. However, embodiments of the present disclosure are not limited thereto.

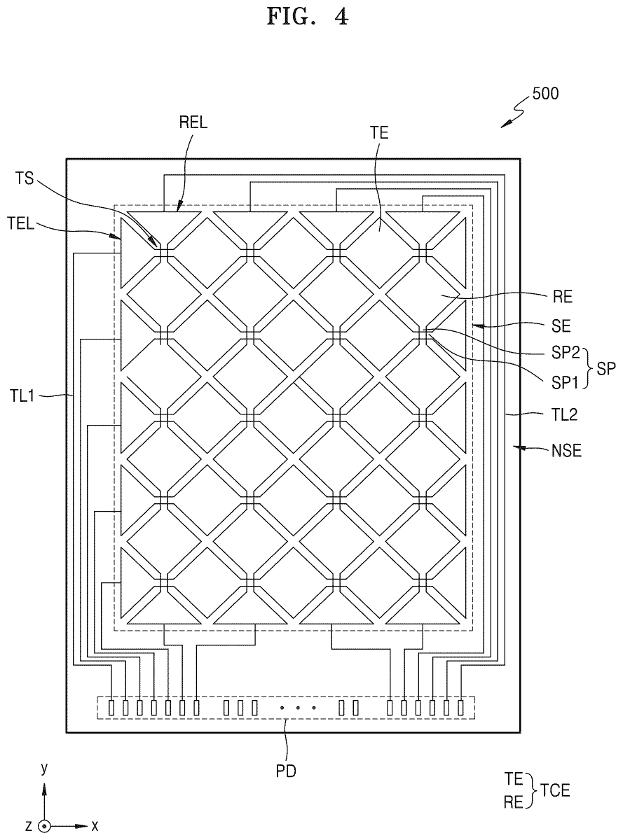

FIG. 4 is a schematic plan view illustrating an input detection layer of a display apparatus according to one or more embodiments.

Referring to FIG. 4, the input detection layer 500 that generates an electrical signal and performs an operation according to a user touch is illustrated. According to one or more embodiments, the input detection layer 500 may be of an electrostatic capacitive type or kind. According to one or more embodiments, the input detection layer 500 may be of a mutual capacitive type or kind.

The input detection layer 500 may include a touch sensor TS including a touch electrode TCE. The input detection layer 500 may include a plurality of touch electrodes TCEs. These plurality of touch electrodes TCEs may be electrically connected to each other through connection patterns SPs. An outer area of the plurality of touch electrodes TCEs may further include signal wirings TL1 and TL2 that are to connect the plurality of touch electrodes TCEs to an external driving circuit through a pad portion PD.

According to one or more embodiments, if (e.g., when) the input detection layer 500 is not provided as a separate panel as in FIG. 3, but is directly on the display element layer 200, the touch electrodes TCEs and the connection patterns SPs of the input detection layer 500 may be provided on the encapsulation layer 400 (refer to FIG. 3). According to one or more embodiments, if (e.g., when) the input detection layer 500 is provided as a separate panel, the touch electrodes TCEs and the connection patterns SPs may be provided on a separate transparent substrate.

The plurality of touch electrodes TCEs may include driving electrodes TEs that are to be connected to each other in a first direction (e.g., an x-axis direction) and detection electrodes REs that are to be distributed between the driving electrodes TEs not to overlap the driving electrodes TEs and connected in a second direction (e.g., a y-axis direction) normal (e.g., substantially perpendicular) to the first direction (e.g., an x-axis direction). The driving electrodes TEs and the detection electrodes REs may be provided alternately not to overlap each other.

The first direction (e.g., an x-axis direction) in which the driving electrodes TEs are connected to each other and the second direction (e.g., a y-axis direction) in which the detection electrodes REs are connected to each other may be substantially different directions intersecting with each other, for example, if (e.g., when) the first direction (e.g., an x-axis direction) is set to a row direction, the second direction (e.g., a y-axis direction) may be set to a column direction.

For example, the driving electrodes TEs may be provided in multiples (e.g., in a plurality) in a plurality of columns and/or rows, respectively, and the driving electrodes TEs in substantially the same column and/or row may be provided to be connected to each other in the first direction (e.g., an x-axis direction) by first connection patterns SP1 provided in multiples (e.g., in a plurality) in substantially the same column and/or row. A configuration or arrangement in which the plurality of driving electrodes TEs are connected in substantially the same column and/or row is referred to as a driving electrode line TEL. For example, one driving electrode line TEL may extend in the first direction (e.g., an x-axis direction), or the plurality of driving electrode lines TELs may be in the second direction (e.g., a y-axis direction). The driving electrode lines TELs may be connected to each first signal wiring TL1 in line units. The first signal wiring TL1 may be a wiring that is to transmit a touch driving signal applied from a touch driving unit to the driving electrodes TEs of the input detection layer 500. For example, the touch driving signal may be applied to the driving electrodes TEs through the first signal wirings TL1.

The detection electrodes REs may be provided in multiples (e.g., in a plurality) in a plurality of rows and/or columns, respectively, and the detection electrodes REs in substantially the same row and/or column may be provided to be connected to each other in the second direction (e.g., a y-axis direction) intersecting with the first direction by second connection patterns SP2 provided in multiples (e.g., in a plurality) in substantially the same row and/or column. A configuration in which the plurality of detection electrodes REs are connected in substantially the same column and/or row is referred to as a detection electrode line REL. For example, one detection electrode line REL may extend in the second direction (e.g., a y-axis direction), and the plurality of detection electrode lines RELs may be provided in the first direction (e.g., an x-axis direction). The detection electrode lines RELs may be connected to each second signal wiring TL2 in line units. The second signal wiring TL2 may be a wiring that is to transmit a touch detection signal to a touch driver. For example, the touch driver may be electrically connected to the detection electrodes REs through the second signal wiring TL2 and may be to receive the touch detection signal from the detection electrodes REs. The touch detection signal may be a signal that is to reflect a change in capacitance between the driving electrodes TEs and the detection electrodes REs.

The touch electrodes TCEs may be implemented transparently (e.g., substantially transparently) to have a certain transmittance or more to transmit light from the display element layer 200 at a lower side therethrough. For example, the touch electrodes TCEs may be provided to include a transparent electrode layer including at least a transparent electrode material, such as indium tin oxide (ITO).

The connection patterns SPs may include a plurality of first connection patterns SP1 provided in the first direction (e.g., an x-axis direction) and connecting the driving electrodes TEs to each other in the first direction (e.g., an x-axis direction) and a plurality of second connection patterns SP2 provided in the second direction and connecting the detection electrodes REs to each other in the second direction. These connection patterns SPs may include a transparent (e.g., substantially transparent) electrode material or opaque (e.g., substantially opaque), low-resistance (e.g., low electrical resistance) electrode material, but the thickness and width thereof may be adjusted to prevent or reduce visibility (e.g., a degree of visibility).

The signal wirings TL1 and TL2 may be electrically connected to the driving electrodes TEs and the detection electrodes REs of line units connected in the first direction (e.g., an x-axis direction) and the second direction (e.g., a y-axis direction), respectively, and thus may be connected to an external driving circuit, such as a touch driver through the pad portion PD. The signal wirings TL1 and TL2 may be in a touch-inactive area NSE defined in an outer area of a touch-active area SE to avoid the touch-active area SE in which an image is displayed and may have a wide range of material selection including a low-resistance (e.g., low electrical resistance) material, such as molybdenum (Mo), silver (Ag), titanium (Ti), copper (Cu), aluminum (AI), and/or molybdenum/aluminum/molybdenum (Mo/Al/Mo) as well as a transparent (e.g., substantially transparent) electrode material used to provide the touch electrodes TCEs.

Although FIG. 4 illustrates one or more embodiments in which the first connection patterns SP1 and the second connection patterns SP2 intersect with each other, embodiments of the present disclosure are not necessarily limited thereto. For example, the first connection patterns SP1 may be connected to the driving electrodes TEs in the first direction without intersecting with the second connection patterns SP2 by a detour that overlaps adjacent detection electrodes REs. In one or more embodiments, an insulating (e.g., electrically insulating) film may be between the first connection patterns SP1 and the detection electrodes REs to ensure substantial stability (e.g., electrical, structural, and/or physical stabilities).

The input detection layer 500 having the structure as described in one or more embodiments may be to detect a touch location by measuring the electrostatic capacitance that changes between the driving electrodes TEs and the detection electrodes REs if (e.g., when) an input device, such as a finger, approaches and/or comes into contact with the input detection layer 500.

The plurality of driving electrodes TEs and the plurality of detection electrodes REs may be provided in a structure in which a plurality of consecutive diamond-shaped (e.g., substantially diamond-shaped) polygons are connected, but embodiments of the present disclosure are not limited thereto. The shape, size, and/or arrangement of the plurality of driving electrodes TEs and the plurality of detection electrodes REs may be suitably changed or modified depending on the shape, size, and/or detection method of a display area in which pixels are provided.

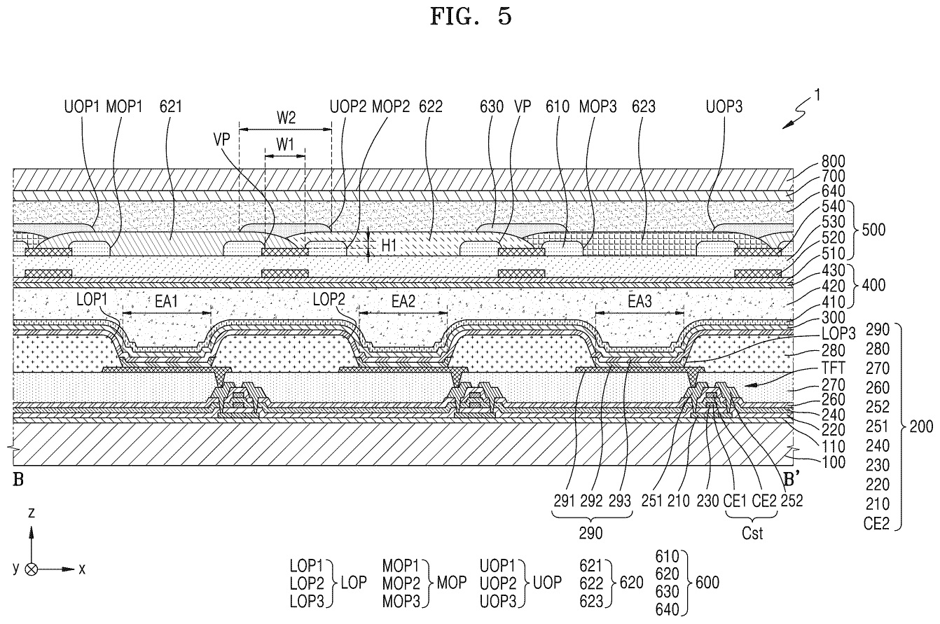

FIG. 5 is a schematic cross-sectional view illustrating a portion of a display apparatus according to one or more embodiments. For example, FIG. 5 is a cross-sectional view taken along a line B-B′ of FIG. 1.

As illustrated in FIG. 5, the display apparatus may include the substrate 100, the display element layer 200, the low reflective layer 300, the encapsulation layer 400, the input detection layer 500, the light control layer 600, the adhesive layer 700, and the protective layer 800.

The substrate 100 may include glass, metal, and/or a polymer resin. It may be desirable for the substrate 100 to have flexible (e.g., substantially flexible) and/or bendable (e.g., substantially bendable) characteristics. In one or more embodiments, the substrate 100 may include a polymer resin, for example, polyethersulfone, polyacrylate, polyetherimide, polyethylene naphthalate, polyethylene terephthalate, polyphenylene sulfide, polyarylate, polyimide, polycarbonate, and/or cellulose acetate propionate. The substrate 100 may have one or more suitable modifications, such as a multilayer structure including two layers including such a polymer resin and a barrier layer provided between the layers and including an inorganic material (such as silicon oxide, silicon nitride, and/or silicon oxynitride).

A buffer layer 110 including silicon oxide, silicon nitride, and/or silicon oxynitride may be on the substrate 100. The buffer layer 110 may increase or enhance the smoothness of an upper surface of the substrate 100 and/or prevent or reduce metal atoms and/or undesirable impurities from the substrate 100 from diffusing into a semiconductor layer 210 thereon. The buffer layer 110 may include a single layer or a multilayer structure including silicon oxide, silicon nitride, and/or silicon oxynitride.

The display element layer 200 may be on the buffer layer 110. The display element layer 200 may include a light-emitting device 290, a thin film transistor TFT to which the light-emitting device 290 is electrically connected, and a storage capacitor Cst. In FIG. 4, an organic light-emitting device is illustrated as being on the buffer layer 110. The organic light-emitting device being electrically connected to the thin film transistor TFT may be understood as referring to a pixel electrode 291 of the organic light-emitting device that is electrically connected to the thin film transistor TFT.

The thin film transistor TFT, as illustrated in FIG. 5, may include the semiconductor layer 210 including amorphous silicon, polycrystalline silicon, an oxide semiconductor material, and/or an organic semiconductor material, a gate electrode 230, a source electrode 251, and a drain electrode 252. The gate electrode 230 may include a material having excellent or suitable conductivity (e.g., electrical conductivity). The gate electrode 230 may include a conductive (e.g., electrically conductive) material including molybdenum (Mo), aluminum (AI), copper (Cu), and/or titanium (Ti) and may be provided as a multilayer structure or a single layer including the conductive (e.g., electrically conductive) material.

To ensure insulation (e.g., electrical insulation) between the semiconductor layer 210 and the gate electrode 230, a gate insulating layer 220 including an inorganic material, such as a silicone oxide, a silicon nitride and/or a silicon oxynitride, may be between the semiconductor layer 210 and the gate electrode 230. A first interlayer insulating layer 240 including an inorganic material, such as silicon oxide, silicon nitride, and/or silicon oxynitride, may be on the gate electrode 230. The first interlayer insulating layer 240 may be provided as a single layer or a plurality of layers (e.g., a multilayer structure) including the material as described in one or more embodiments. An insulating (e.g., electrically insulating) film containing the inorganic material may be provided via a deposition method, such as chemical vapor deposition (CVD) and/or atomic layer deposition (ALD). Substantially the same description may also be applied to the embodiments and modified embodiments as described in more detail herein.

The storage capacitor Cst may include a first electrode CE1 and a second electrode CE2 that are to overlap each other with the first interlayer insulating layer 240 therebetween. The storage capacitor Cst may be to overlap the thin film transistor TFT. regarding one or more embodiments, FIG. 5 illustrates that the gate electrode 230 of the thin film transistor TFT may be the first electrode CE1 of the storage capacitor Cst, but embodiments of the present disclosure are not limited thereto. For example, the storage capacitor Cst may not be to overlap the thin film transistor TFT. The second electrode CE2 of the storage capacitor Cst may include a conductive (e.g., electrically conductive) material including molybdenum (Mo), aluminum (Al), copper (Cu), and/or titanium (Ti) and may be provided as a multilayer structure or a single layer including the material.

A second interlayer insulating layer 260 including an inorganic material, such as silicon oxide, silicon nitride, and/or silicon oxynitride, may be on the second electrode CE2 of the storage capacitor Cst. The second interlayer insulating layer 260 may be provided as a single layer or a plurality of layers (e.g., a multilayer structure) including the material as described in one or more embodiments.

The source electrode 251 and the drain electrode 252 may be on the second interlayer insulating layer 260. The source electrode 251 and the drain electrode 252 may include a material having excellent or suitable conductivity (e.g., electrical conductivity). The source electrode 251 and the drain electrode 252 may include a conductive (e.g., electrically conductive) material including molybdenum (Mo), aluminum (Al), copper (Cu), and/or titanium (Ti) and may be provided as a multilayer structure or a single layer including the material. For example, the source electrode 251 and the drain electrode 252 may be provided as a multilayer structure of Ti/Al/Ti.

A planarization layer 270 may be on the thin film transistor TFT. For example, if (e.g., when) the light-emitting device 290 is on the thin film transistor TFT as shown in FIG. 5, the planarization layer 270 may be to generally planarize an upper portion of the thin film transistor TFT. The planarization layer 270 may include an organic material, such as, for example, acrylic, benzocyclobutene (BCB), and/or hexamethyldisiloxane (HMDSO). In FIG. 5, the planarization layer 270 is illustrated as a single layer, but one or more suitable modifications may be made, such as a multilayer structure.

Within the display area DA of the display element layer 200, the light-emitting device 290 may be on the planarization layer 270. The light-emitting device 290 may be, for example, an organic light-emitting diode having the pixel electrode 291, a counter electrode 293, and an intermediate layer 292 therebetween and including an emission layer.

The pixel electrode 291 may be in contact with one of the source electrode 251 and the drain electrode 252 through an opening provided through the planarization layer 270 and may be connected to the thin film transistor TFT, as illustrated in FIG. 5. The pixel electrode 291 may include a light-transmitting conductive (e.g., electrically conductive) layer including a light-transmitting conductive (e.g., electrically conductive) oxide, such as indium tin oxide (ITO), indium oxide (e.g., In₂O₃), and/or indium zinc oxide (IZO), and a reflective (e.g., substantially reflective) layer including a metal, such as Al and/or Ag. For example, the pixel electrode 291 may have a three-layer structure of ITO/Ag/ITO.

A bank layer 280 may be on the planarization layer 270. The bank layer 280 may include lower openings LOPs corresponding to respective pixels. For example, the bank layer 280 may have a lower opening LOP that is to expose a central portion of the pixel electrode 291 therethrough, thereby to define a pixel and an emission area. For example, the bank layer 280 may include a first lower opening LOP1 to define a first emission layer EA1, a second lower opening LOP2 to define a second emission area EA2, and a third lower opening LOP3 to define a third emission area EA3. In one or more embodiments, the wavelength of light emitted from the first emission layer EA1 may be in a range of about 630 nm to about 750 nm, the wavelength of light emitted from the second emission area EA2 may be in a range of about 490 nm to about 570 nm, and the wavelength of light emitted from the third emission area EA3 may be in a range of about 450 nm to about 490 nm. For example, red light may be emitted in the first emission layer EA1, green light may be emitted in the second emission area EA2, and blue light may be emitted in the third emission area EA3.

As shown in FIG. 4, the bank layer 280 may be to prevent or reduce arcs

and/or the like from occurring at an edge of the pixel electrode 291 by increasing a distance between the edge of the pixel electrode 291 and the counter electrode 293 above the pixel electrode 291. The bank layer 280 may include an organic material, such as polyimide and/or hexamethyldisiloxane (HMDSO).

The bank layer 280 may include a light-blocking material and may be provided as a black (e.g., substantially black) material. The light-blocking material may include a resin and/or a paste containing carbon black, carbon nanotubes, black dye, metal particles, such as nickel, aluminum, molybdenum, and alloys thereof, metal oxide particles (e.g., chromium oxide) and/or metal nitride particles (e.g., chromium nitride). If (e.g., when) the bank layer 280 includes the light-blocking material, external light reflection (e.g., a degree or occurrence of external light reflection) by metal structures below the bank layer 280 may be reduced.

The intermediate layer 292 of the light-emitting device 290 may include a low-molecular weight material and/or a high-molecular weight material. If (e.g., when) the intermediate layer 292 includes a low-molecular weight material, the intermediate layer 292 may have a structure in which a hole injection layer (HIL), a hole transport layer (HTL), an emission layer (EML), an electron transport layer (ETL), and an electron injection layer (EIL) are stacked in a single or composite structure and may be provided using a vacuum deposition method, such as chemical vapor deposition (CVD) and/or atomic layer deposition (ALD). If (e.g., when) the intermediate layer 292 includes a high-molecular weight material, the intermediate layer 292 may have a structure including an HTL and/or an EML. In one or more embodiments, the HTL may include poly(3,4-ethylenedioxythiophene) (PEDOT), and the EML may include a high-molecular weight material, such as polyphenylene vinylene (PPV) and/or polyfluorene. The intermediate layer 292 may be provided via screen printing, inkjet printing, laser induced thermal imaging (LITI), and/or the like. The intermediate layer 292 may not be necessarily limited thereto and may have one or more suitable structures. The intermediate layer 292 may include a layer that is integral across the plurality of pixel electrodes 291 or may include a layer patterned to correspond to each of the plurality of pixel electrodes 291.

The counter electrode 293 may be above the display area DA and may be to cover the display area DA. For example, the counter electrode 293 may be provided integrally in a plurality of organic light-emitting devices and correspond to the plurality of pixel electrodes 291. The counter electrode 293 may include a light-transmitting conductive (e.g., electrically conductive) layer including ITO, indium oxide (e.g., In₂O₃), and/or IZO and may also include a semi-transmitting film including a metal, such as Al and/or Ag. For example, the counter electrode 293 may be a semi-transmitting film containing Mg and/or Ag.

The low reflective layer 300 may be on the display element layer 200. For example, the low reflective layer 300 may be between the display element layer 200 and the encapsulation layer 400. The low reflective layer 300 may include an inorganic material having substantially low reflectivity. The low reflective layer 300 may include, for example, ytterbium (Yb), bismuth (Bi), cobalt (Co), molybdenum (Mo), titanium (Ti), zirconium (Zr), aluminum (Al), chromium (Cr), niobium (Nb), platinum (Pt), tungsten (W), indium (In), tin (Sn), iron (Fe), nickel (Ni), tantalum (Ta), manganese (Mn), zinc (Zn), germanium (Ge), or a combination thereof. In some embodiments, the low reflective layer 300 may not be provided.

The low reflective layer 300 may reduce external light reflection (or a degree or occurrence of external light reflection) by inducing destructive interference between light incident on the inside of the display apparatus and light reflected from metal below the low reflective layer 300. Therefore, the display quality and visibility (e.g., a degree of visibility) of the display apparatus may be improved or enhanced by reducing the external light reflectivity (or by reducing a degree or occurrence of external light reflectivity) of the display apparatus through the low reflective layer 300.

The encapsulation layer 400 may be on the low reflective layer 300. The encapsulation layer 400 may be to cover the display area DA (FIG. 1) and may be to extend to the outside of the display area DA (FIG. 1). The encapsulation layer 400 may include a first inorganic encapsulation layer 410, an organic encapsulation layer 420, and a second inorganic encapsulation layer 430, as shown in FIG. 5.

The first inorganic encapsulation layer 410 may be to cover the low reflective layer 300 and may include silicon oxide, silicon nitride, and/or silicon oxynitride. The first inorganic encapsulation layer 410 may be along a structure therebelow, and thus an upper surface thereof may not be flat (e.g., substantially flat), as shown in FIG. 4.

The organic encapsulation layer 420 may be to cover the first inorganic encapsulation layer 410 and may have a substantially flat upper surface unlike the first inorganic encapsulation layer 410. For example, the organic encapsulation layer 420 may have an upper surface that is approximately or substantially flat in a portion corresponding to the display area DA (FIG. 1). The organic encapsulation layer 420 may include a first organic material. The first organic material may include one or more materials selected from the group consisting of, for example, polyethylene terephthalate, polyethylene naphthalate, polycarbonate, polyimide, polyethylene sulfonate, polyoxymethylene, polyarylate, hexamethyldisiloxane, epoxy resins, and acrylic resins (e.g., polymethyl methacrylate and/or polyacrylic acid).

The second inorganic encapsulation layer 430 may be to cover the organic encapsulation layer 420 and may include silicon oxide, silicon nitride, and/or silicon oxynitride. The second inorganic encapsulation layer 430 may be in contact with the first inorganic encapsulation layer 410 at an edge of the second inorganic encapsulation layer 430, which is outside the display area DA (FIG. 1) to prevent the organic encapsulation layer 420 from being exposed to the outside.

As such, the encapsulation layer 400 may include the first inorganic encapsulation layer 410, the organic encapsulation layer 420, and the second inorganic encapsulation layer 430, and thus even if (e.g., when) cracks occur within the encapsulation layer 400, the cracks may be prevented from being connected between the first inorganic encapsulation layer 410 and the organic encapsulation layer 420 or between the organic encapsulation layer 420 and the second inorganic encapsulation layer 430 (or a likelihood, occurrence, or degree of such connecting cracks may be reduced). This may prevent, reduce, or minimize formation of a path through which moisture and/or oxygen from the outside penetrates the display area DA (FIG. 1). The light-emitting device 290 as described in one or more embodiments may be easily damaged by moisture and/or oxygen from the outside, and the encapsulation layer 400 may be to cover and protect the organic light-emitting device and/or the low reflective layer 300.

The input detection layer 500 may be on the encapsulation layer 400. The input detection layer 500 may be to obtain coordinate information according to an external input, for example, a touch event of an object, such as a finger and/or a stylus pen. The input detection layer 500 may include detection electrodes and/or a trace line. The input detection layer 500 may be to detect an external input by using a mutual cap method and/or a self-cap method.

The input detection layer 500 may include a first conductive layer 520 (e.g., a first layer that is electrically conductive) and a second conductive layer 540 (e.g., a second layer that is electrically conductive), which each include a detection electrode and/or a trace line. A first touch insulating layer 510 may be between the encapsulation layer 400 and the first conductive layer 520, and a second touch insulating layer 630 may be between the first conductive layer 520 and the second conductive layer 540.

The first conductive layer 520 and the second conductive layer 540 may include a single layer or a plurality of layers (e.g., a multilayer structure) containing a conductive (e.g., electrically conductive) material. The conductive (e.g., electrically conductive) material may include molybdenum (Mo), aluminum (Al), copper (Cu), and/or titanium (Ti). For example, the first conductive layer 520 and the second conductive layer 540 may have a three-layer structure of Ti/Al/Ti.

The first conductive layer 520 and the second conductive layer 540 may

include a single layer or a plurality of layers (e.g., a multilayer structure) containing a conductive (e.g., electrically conductive) material. The conductive (e.g., electrically conductive) material may include molybdenum (Mo), aluminum (Al), copper (Cu), and/or titanium (Ti). For example, the first conductive layer 520 and the second conductive layer 540 may have a three-layer structure of Ti/Al/Ti.

The first touch insulating layer 510 may include an inorganic insulating (e.g., electrically insulating) material and/or an organic insulating (e.g., electrically insulating) material. The inorganic insulating material may include silicon oxide, silicon nitride, and/or silicon oxynitride, and the organic insulating material may include an acrylic organic material and/or an imide organic material. A second touch insulating layer 530 may be an organic insulating material including an acrylic organic material and/or an imide organic material.

According to one or more embodiments, referring to FIGS. 4-5, the first conductive layer 520 may include the second connection patterns SP2 connecting the plurality of detection electrodes REs to each other. The second conductive layer 540 may include the plurality of detection electrodes REs, the plurality of driving electrodes TEs, and the first connection patterns SP1 connecting the plurality of driving electrodes TEs to each other. For example, the plurality of driving electrodes TEs may be connected to each other by the first connection patterns SP1 on substantially the same layer, and the plurality of detection electrodes REs may be connected to each other by the second connection patterns SP2 on substantially different layers through a contact hole. According to one or more embodiments, the plurality of driving electrodes TEs and the first connection patterns SP1 may be provided integrally.

The light control layer 600 may be on the input detection layer 500. The light control layer 600 may include a first light-blocking layer 610, a color filter layer 620, a second light-blocking layer 630, and an overcoat layer 640. The first light-blocking layer 610, the color filter layer 620, the second light-blocking layer 630, and the overcoat layer 640 may be stacked and provided sequentially.

The first light-blocking layer 610 may include a middle opening MOP corresponding to each of emission layers EA1, EA2, and EA3 of the light-emitting device 290. For example, the first light-blocking layer 610 may include a first middle opening MOP1 corresponding to the first emission layer EA1, wherein the first middle opening MOP1 may be to overlap the first lower opening LOP1, a second middle opening MOP2 corresponding to the second emission area EA2, wherein the second middle opening MOP2 may be to overlap the second lower opening LOP2, and a third middle opening MOP3 corresponding to the third emission area EA3, wherein the third middle opening MOP3 may be to overlap the third lower opening LOP3. The first light-blocking layer 610 may include the plurality of middle openings MOPs, and thus may have a lattice shape (e.g., a substantially lattice shape) and/or a mesh pattern (e.g., substantially mesh pattern). A planar width of the middle opening MOP of the first light-blocking layer 610 may be greater than a planar width of the lower opening LOP of the bank layer 280.

The first light-blocking layer 610 may include a light-blocking material and may include a black (e.g., substantially black) material. The light-blocking material may include a resin and/or a paste containing carbon black, carbon nanotubes, black dye, and/or metal particles. The metal particles may include, for example, nickel, aluminum, molybdenum and/or alloys thereof. The light-blocking material may include metal oxide particles, such as chromium oxide, and/or metal nitride particles, such as chromium nitride. The first light-blocking layer 610 may include a light-blocking material, and thus external light reflection (or a degree or occurrence of external light reflection) by metal structures below the first light-blocking layer 610 may be reduced. As needed, the first light-blocking layer 610 may include substantially the same material as the bank layer 280 therebelow. However, embodiments of the present disclosure are not limited thereto, and the first light-blocking layer 610 may include a material substantially different from the bank layer 280.

The color filter layer 620 may be on the first light-blocking layer 610. The color filter layer 620 may include a plurality of color filters, including a first color filter 621, a second color filter 622, and a third color filter 623. According to one or more embodiments, the first middle opening MOP1 corresponding to the first emission layer EA1 may be filled with the first color filter 621, the second middle opening MOP2 corresponding to the second emission area EA2 may be filled with the second color filter 622, and the third middle opening MOP3 corresponding to the third emission area EA3 may be filled with the third color filter 623.

For the display apparatus 1, a color filter may be above each pixel to reduce external light reflection (or to reduce a degree or occurrence of external light reflection). For example, for a pixel that emits red light, a red color filter that allows red light alone to pass therethrough may be on the pixel, and for a pixel that emits blue light, a blue color filter that allows blue light alone to pass therethrough may be on the pixel. In one or more embodiments, if (e.g., when) external light, such as white light, is incident on the red color filter, for example, blue light and green light may be absorbed by the red color filter, and red light alone may pass through the red color filter, may be reflected by the pixel electrode 291, may pass through the red color filter again, and may be emitted to the outside. Therefore, for the display apparatus 1 having the color filter layer 620, external light reflection (or a degree or occurrence of external light reflection) may be reduced to approximately 1/3 compared to the case without a color filter layer 620.

For example, the first color filter 621, the second color filter 622, and the third color filter 623 may have colors corresponding to light emitted from the respective emission layers of the light-emitting device 290 provided below each color filter. For example, if (e.g., when) red light is emitted from the emission layer of the light-emitting device 290 provided below the first color filter 621, the first color filter 621 may be a red color filter, and if (e.g., when) green light is emitted from the emission layer of the light-emitting device 290 provided below the second color filter 622, the second color filter 622 may be a green color filter. If (e.g., when) blue light is emitted from the emission layer of the light-emitting device 290 provided below the third color filter 623, the third color filter 623 may be a blue color filter.

According to one or more embodiments, the plurality of color filters may be to at least partially overlap each other in a non-emission area. For example, two color filters from among the plurality of color filters adjacent to each other may be to overlap each other in an area that overlaps the bank layer 280, the first conductive layer 520, and the second conductive layer 540. For example, the first color filter 621 and the second color filter 622 may be to overlap each other in an area above the bank layer 280 between the first emission layer EA1 and the second emission area EA2. In one or more embodiments, the second color filter 622 and the third color filter 623 may be to overlap each other in an area above the bank layer 280 between the second emission area EA2 and the third emission area EA3. If (e.g., when) color filters of different colors are stacked, a color filter overlapping portion may be to absorb light of a wider wavelength band than a single color filter. In one or more embodiments, the color filter overlapping portion may be to block light like the first light-blocking layer 610.

The second light-blocking layer 630 may be on the color filter layer 620. The second light-blocking layer 630 may include an upper opening UOP corresponding to each of the emission areas EA1, EA2, and EA3 of the light-emitting device 290 like the first light-blocking layer 610. For example, the second light-blocking layer 630 may include a first upper opening UOP1 corresponding to the first emission layer EA1, wherein the first upper opening UOP1 may be to overlap the first lower opening LOP1, a second upper opening UOP2 corresponding to the second emission area EA2, wherein the second upper opening UOP2 may be to overlap the second lower opening LOP2, and a third upper opening UOP3 corresponding to the third emission area EA3, wherein the third upper opening UOP3 may be to overlap the third lower opening LOP3. The second light-blocking layer 630 may include the plurality of upper openings UOPs, and thus may have a lattice shape (e.g., a substantially lattice shape) and/or a mesh pattern (e.g., a substantially mesh shape). A planar width of the upper opening UOP of the second light-blocking layer 630 may be greater than a planar width of the lower opening LOP of the bank layer 280. The planar width of the upper opening UOP of the second light-blocking layer 630 may be greater than the planar width of the middle opening MOP of the first light-blocking layer 610.

The second light-blocking layer 630 may include the upper opening UOP, and thus the second light-blocking layer 630 may be to overlap at least a portion of the first light-blocking layer 610 in a planar manner. In one or more embodiments, the second light-blocking layer 630 may be to overlap the color filter overlapping portion, the first conductive layer 520, and/or the bank layer 280 in a planar manner.

The second light-blocking layer 630 may include a light-blocking material and may include a black (e.g., substantially black) material. The light-blocking material may include a resin and/or a paste containing carbon black, carbon nanotubes, black dye, and/or metal particles. The metal particles may include, for example, nickel, aluminum, molybdenum, and/or alloys thereof. The light-blocking material may include metal oxide particles, such as chromium oxide, and/or metal nitride particles, such as chromium nitride. According to one or more embodiments, the second light-blocking layer 630 may include substantially the same material as the first light-blocking layer 610. However, embodiments of the present disclosure are not limited thereto, and the second light-blocking layer 630 may include a material substantially different from the first light-blocking layer 610.

The display apparatus 1 according to one or more embodiments may reduce external light reflectivity (e.g., a degree or occurrence of external light reflectivity) by locating the second light-blocking layer 630 including a light-blocking material on the color filter layer 620. For example, in an area in which ends of respective color filters of the color filter layer 620 overlap each other, diffuse reflectance caused by overlapping of the color filters may occur, thereby reducing visibility (e.g., a degree of visibility). In one or more embodiments, the second light-blocking layer 630 may be on the color filter overlapping portion, and thus diffuse reflectance may be controlled, thereby reducing reflectivity and improving or enhancing display quality.

However, the first light-blocking layer 610 and the second light-blocking layer 630 may include a light blocking material, and thus may reduce reflection of external light (e.g., a degree or occurrence of reflection of external light), while also substantially blocking light emitted from the light-emitting device 290. In one or more embodiments, it may be desirable for the first light-blocking layer 610 and the second light-blocking layer 630 to be with an appropriate or suitable area to increase an aperture ratio of each pixel. For example, to ensure or provide a viewing angle, a planar area of the middle opening MOP may be greater than a planar area of the lower opening LOP, and a planar area of the upper opening UOP may be greater than the planar area of the middle opening MOP. For example, an end of the bank layer 280, which faces the lower opening LOP, may protrude further than an end of the first light-blocking layer 610, which faces the middle opening MOP, and an end of the first light-blocking layer 610, which faces the middle opening MOP, may protrude further than an end of the second light-blocking layer 630, which faces the upper opening UOP. For example, the planar width of the first light-blocking layer 610 may be less than the planar width of the bank layer 280, and a planar width W2 of the second light-blocking layer 630 may be less than the planar width of the first light-blocking layer 610.

For example, the second light-blocking layer 630 may be on the color filter overlapping portion, and thus, as the thickness of the color filter overlapping portion increases, it may be desirable for an area of the second light-blocking layer 630 to decrease to ensure a viewing angle. For example, as the thickness of the color filter overlapping portion increases, the planar width W2 of the second light-blocking layer 630 may decrease, and as the thickness of the color filter overlapping portion decreases, the planar width W2 of the second light-blocking layer 630 may increase.

In one or more embodiments, to increase the planar area of the second light-blocking layer 630 and reduce reflectivity (e.g., a degree or occurrence of reflectivity) in the display apparatus 1 according to one or more embodiments, the first light-blocking layer 610 may further include a valley pattern VP. The valley pattern VP may be defined in the first light-blocking layer 610.

The valley pattern VP may have a recessed shape (e.g., a substantially recessed shape) in a thickness direction (e.g., z direction) of the first light-blocking layer 610 from an upper surface of the first light-blocking layer 610 in a cross section. The valley pattern VP having a recessed shape (e.g., a substantially recessed shape) may include a lower surface and a lateral surface, and the lateral surface may have a shape that is inclined (e.g., substantially inclined) at a certain angle based on the lower surface. For example, a taper angle of the lateral surface of the valley pattern VP from the lower surface may be about 70 degrees to about 90 degrees. The valley pattern VP may be provided by having a shape that is dug in a third direction (e.g., z direction) and extends in a second direction (e.g., y direction). In one or more embodiments, in another cross section, the valley pattern VP may be to extend in a first direction (e.g., x direction). For example, the valley pattern VP may have a mesh pattern (e.g., a substantially mesh pattern) like the first light-blocking layer 610.

According to one or more embodiments, the valley pattern VP may be in a non-emission area. For example, the valley pattern VP may be to overlap the bank layer 280, the first conductive layer 520, and the second conductive layer 540. The valley pattern VP may be between adjacent middle openings MOPs from among the plurality of middle openings MOPs. For example, the valley pattern VP may be between the first middle opening MOP1 and the second middle opening MOP2 and may be between the second middle opening MOP2 and the third middle opening MOP3.

The valley pattern VP may have a shape provided by recessing the first light-blocking layer 610 and may be to overlap the second conductive layer 540, and thus the valley pattern VP may be to expose the upper surface of the second conductive layer 540 therethrough. However, the valley pattern VP may be to expose a central 1 portion alone of the upper surface of the second conductive layer 540 and may not be to expose an end of the second conductive layer 540. For example, the first light-blocking layer 610 may be to cover the end of the second conductive layer 540. As the first light-blocking layer 610 covers the end of the second conductive layer 540, for example, as the first light-blocking layer 610 clads the second conductive layer 540, erosion of the second conductive layer 540, which may occur in a post-process, may be prevented (or a likelihood, degree or occurrence of the erosion may be reduced). The first light-blocking layer 610 may be to cover the end of the second conductive layer 540, and thus a planar width W1 of the valley pattern VP may be less than the planar width of the second conductive layer 540.

According to one or more embodiments, the valley pattern VP may be filled with the color filter layer 620. For example, the valley pattern VP between the first middle opening MOP1 and the second middle opening MOP2 may be filled with the first color filter 621 and the second color filter 622, and the valley pattern VP between the second middle opening MOP2 and the third middle opening MOP3 may be filled with the second color filter 622 and the third color filter 623. In one or more embodiments, the exposed upper surface of the second conductive layer 540 may be in direct contact with the lower surface of the color filter layer 620.

According to one or more embodiments, the color filter overlapping portion may be in the valley pattern VP. For example, the first color filter 621 and the second color filter 622 may be to at least partially overlap each other on a plane within the valley pattern VP. In one or more embodiments, the second color filter 622 and the third color filter 623 may be to at least partially overlap each other on a plane within the valley pattern VP. The color filter overlapping portion may be within the valley pattern VP, and thus even if (e.g., when) a portion of the first light-blocking layer 610 is removed, the color filter overlapping portion may perform a portion of a function of light blocking.

The first light-blocking layer 610 may include the valley pattern VP, and thus the second light-blocking layer 630 may be provided at a lower location than a structure in which the second light-blocking layer 630 does not include the valley pattern VP. For example, if (e.g., when) the valley pattern VP is in the first light-blocking layer 610, the color filter layer 620 may be filled in the valley pattern VP, and thus a height from the substrate 100 to the upper surface of the color filter overlapping portion may be reduced. The second light-blocking layer 630 may be on the color filter overlapping portion, and thus, as the height of the color filter overlapping portion decreases, the height of the second light-blocking layer 630 may also decrease. For example, the height of the second light-blocking layer 630 may be reduced by a thickness H1 between the upper surface of the first light-blocking layer 610 and an upper surface of the second conductive layer 540.

In one or more embodiments, if (e.g., when) the height of the second light-blocking layer 630 is low, the second light-blocking layer 630 may have a wide area while ensuring a viewing angle. In one or more embodiments, the planar width W2 of the second light-blocking layer 630 may increase as the height of the second light-blocking layer 630 decreases, and the reflectivity (e.g., a degree or occurrence of the reflectivity) of the display apparatus 1 may decrease or reduce as the planar area of the second light-blocking layer 630 increases. In one or more embodiments, in the display apparatus 1 according to one or more embodiments, the first light-blocking layer 610 may be in the valley pattern VP, and thus the planar area of the second light-blocking layer 630 may be increased, thereby reducing reflectivity and improving or enhancing the display quality and visibility (e.g., a degree of visibility) of the display apparatus 1.

Referring to FIG. 5, the overcoat layer 640 may be on the color filter layer 620 and the second light-blocking layer 630. The overcoat layer 640 may be provided integrally across the first emission layer EA1, the second emission area EA2, and/or the third emission area EA3. The overcoat layer 640 may be a colorless (e.g., substantially colorless), light-transmitting (e.g., substantially light-transmitting) layer that does not have a color in a visible light band and may planarize an upper surface of the light control layer 600 including the color filter layer 620. For example, the overcoat layer 640 may include an organic material, such as, for example, acrylic, benzocyclobutene (BCB), and/or hexamethyldisiloxane (HMDSO).

The adhesive layer 700 may be on the light control layer 600, and the protective layer 800 may be on the adhesive layer 700. The adhesive layer 700 may include, for example, a silicon-based adhesive material and/or a urethane-based adhesive material. The protective layer 800 may include a plastic film, such as polyethylene terephthalate. However, embodiments of the present disclosure are not limited thereto.

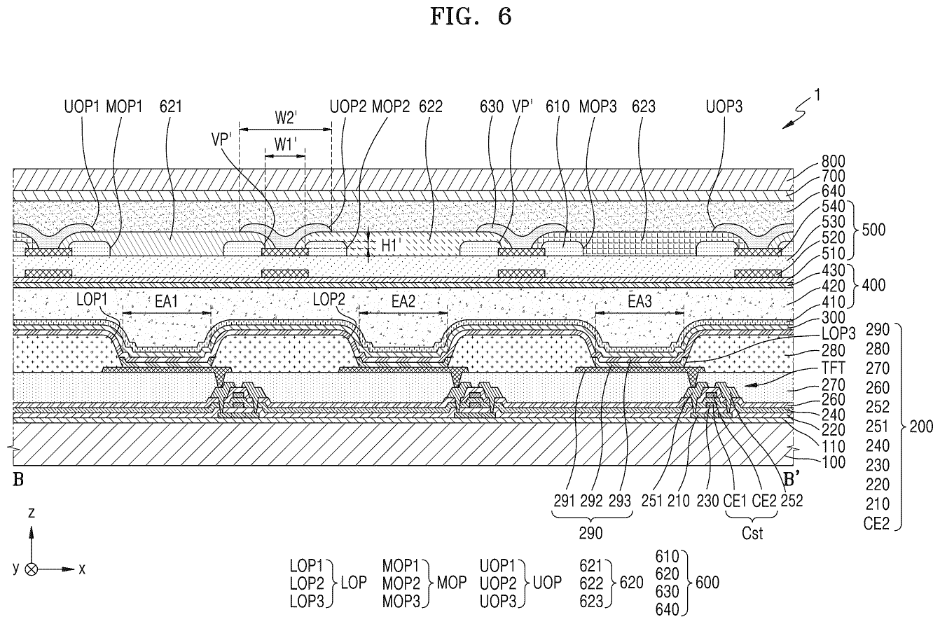

FIG. 6 is a schematic cross-sectional view illustrating a portion of a display apparatus according to one or more embodiments. Referring to FIG. 6, other characteristics except for the characteristics of the light control layer 600 are substantially the same as described in FIG. 5. From among the components in FIG. 6, the same reference numbers are replaced with those described above with reference to FIG. 5, and the following description is given in terms of differences.

Referring to FIG. 6, the light control layer 600 may include the first light-blocking layer 610, the color filter layer 620, the second light-blocking layer 630, and the overcoat layer 640. The first light-blocking layer 610, the color filter layer 620, the second light-blocking layer 630, and the overcoat layer 640 may be stacked and provided sequentially.

The first light-blocking layer 610 may include a valley pattern VP′. The valley pattern VP′ may be defined in the first light-blocking layer 610. The valley pattern VP′ may have a recessed shape (e.g., a substantially recessed shape) in a thickness direction (e.g., z direction) of the first light-blocking layer 610 from an upper surface of the first light-blocking layer 610 in a cross section.

In one or more embodiments, the valley pattern VP′ may be in a non-emission area. For example, the valley pattern VP′ may be to overlap the bank layer 280, the first conductive layer 520, and the second conductive layer 540. The valley pattern VP′ may be between adjacent middle openings MOPs from among the plurality of middle openings MOPs. For example, the valley pattern VP′ may be between the first middle opening MOP1 and the second middle opening MOP2 and may be between the second middle opening MOP2 and the third middle opening MOP3.

The valley pattern VP′ may have a shape provided by recessing the first light-blocking layer 610 and may be to overlap the second conductive layer 540, and thus the valley pattern VP′ may be to expose the upper surface of the second conductive layer 540 therethrough. However, the valley pattern VP′ may be to expose a central portion alone of the upper surface of the second conductive layer 540 and may not be to expose an end of the second conductive layer 540. For example, the first light-blocking layer 610 may be to cover the end of the second conductive layer 540. For example, a planar width W1′ of the valley pattern VP′ may be less than the planar width of the second conductive layer 540.

According to one or more embodiments, the valley pattern VP′ may be filled with the color filter layer 620 and the second light-blocking layer 630. For example, the valley pattern VP′ between the first middle opening MOP1 and the second middle opening MOP2 may be filled with the first color filter 621, the second light-blocking layer 630, and the second color filter 622, and the valley pattern VP′ between the second middle opening MOP2 and the third middle opening MOP3 may be filled with the second color filter 622, the second light-blocking layer 630, and the third color filter 623. In one or more embodiments, the exposed upper surface of the second conductive layer 540 may be in direct contact with the color filter layer 620 and the second light-blocking layer 630.

According to one or more embodiments, a plurality of color filters within the valley pattern VP′ may be spaced and/or apart (e.g., spaced apart or separated) from each other. For example, the first color filter 621 and the second color filter 622 may be spaced and/or apart (e.g., spaced apart or separated) from each other on a plane within the valley pattern VP′. In one or more embodiments, the second color filter 622 and the third color filter 623 may be spaced and/or apart (e.g., spaced apart or separated) from each other on a plane within the valley pattern VP′. As the color filter layer 620 and the second light-blocking layer 630 are sequentially provided, a portion of the second light-blocking layer 630 may be in a separation area as a space provided by spacing the plurality of color filters apart from each other within the valley pattern VP′. For example, the second light-blocking layer 630 may be between the first color filter 621 and the second color filter 622 within the valley pattern VP′. In one or more embodiments, the second light-blocking layer 630 may be between the second color filter 622 and the third color filter 623 within the valley pattern VP′.

The first light-blocking layer 610 may include the valley pattern VP′, and thus the second light-blocking layer 630 may be at a lower location than a structure in which the second light-blocking layer 630 does not include the valley pattern VP′. For example, if (e.g., when) the plurality of color filters are spaced and/or apart (e.g., spaced apart or separated) from each other within the valley pattern VP′ as in FIG. 6, the thickness of the color filter layer 620 in the non-emission area may be less than in a structure in which the plurality of color filters overlap each other within the valley pattern VP′. The second light-blocking layer 630 may be on the color filter layer 620, and thus, as the height of the color filter layer 620 decreases, the height of the second light-blocking layer 630 may also decrease. For example, the height of the second light-blocking layer 630 may have a low height due to the valley pattern VP′ of the first light-blocking layer 610 and the separation arrangement of the color filters. For example, the height of the second light-blocking layer 630 may be reduced to the thickness H1 between the upper surface of the first light-blocking layer 610 and an upper surface of the second conductive layer 540 or more.

In one or more embodiments, if (e.g., when) the height of the second light-blocking layer 630 is low, the second light-blocking layer 630 may have a substantially wider area while ensuring a viewing angle. In one or more embodiments, a planar width W2′ of the second light-blocking layer 630 may increase as the height of the second light-blocking layer 630 decreases, and as the planar area of the second light-blocking layer 630 increases, the reflectivity (e.g., a degree or occurrence of reflectivity) of the display apparatus 1 may decrease. In one or more embodiments, in the display apparatus 1 according to one or more embodiments, the first light-blocking layer 610 may include the valley pattern VP′ and the color filters may be spaced and/or apart (e.g., spaced apart or separated) from each other within the valley pattern VP′, and thus the planar area of the second light-blocking layer 630 may be expanded, thereby reducing the reflectivity (e.g., a degree or occurrence of reflectivity) and efficiently or suitably improving or enhancing the display quality and visibility (e.g., a degree of visibility) of the display apparatus 1.

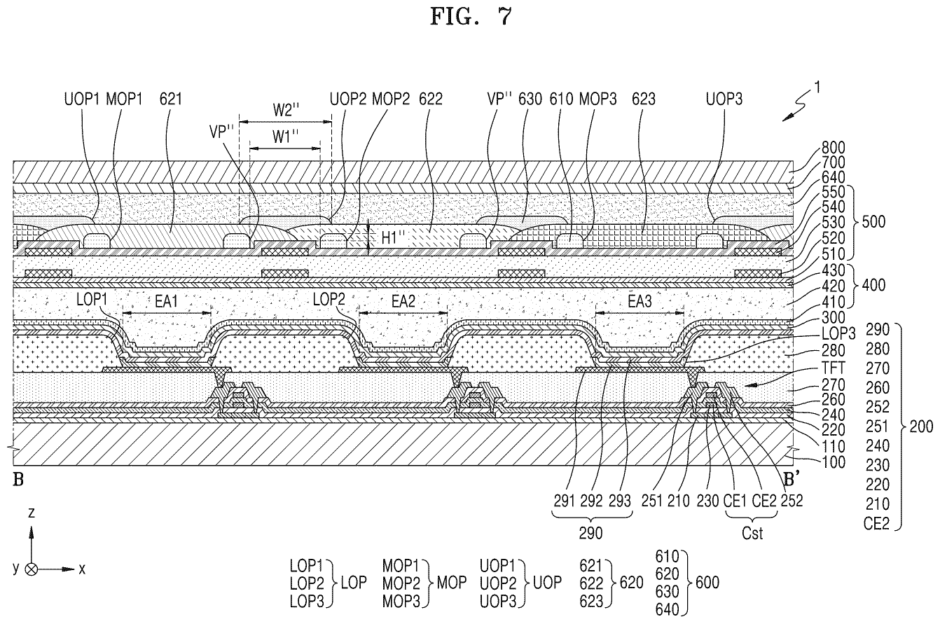

FIG. 7 is a schematic cross-sectional view illustrating a portion of a display apparatus according to one or more embodiments. Referring to FIG. 7, other characteristics except for the characteristics of the input detection layer 500 and the light control layer 600 may be substantially the same as described with reference to FIG. 5. From among the components in FIG. 7, the same reference numbers are replaced with those described above with reference to FIG. 5, and the following description is given in terms of differences.

Referring to FIG. 7, the input detection layer 500 may include the first touch insulating layer 510, the first conductive layer 520, the second touch insulating layer 530, the second conductive layer 540, and a clad layer 550. The first touch insulating layer 510, the first conductive layer 520, the second touch insulating layer 530, the second conductive layer 540, and the clad layer 550 may be provided sequentially. The clad layer 550 may be a layer to prevent erosion (or to reduce a likelihood, degree or occurrence of erosion) of the second conductive layer 540, which may occur during a post-process. The clad layer 550 may be to cover the second conductive layer 540 and may be on an entire (e.g., substantially entire) surface of the substrate 100. In one or more embodiments, a partial area of the clad layer 550 may be to cover the clad layer 550, and another partial area may be in contact with the second touch insulating layer 530. The clad layer 550 may include an inorganic material, such as silicon oxide, silicon nitride, and/or silicon oxynitride.

The light control layer 600 may be on the input detection layer 500. The light control layer 600 may include the first light-blocking layer 610, the color filter layer 620, the second light-blocking layer 630, and the overcoat layer 640. For example, the first light-blocking layer 610 may be on the clad layer 550.

According to one or more embodiments, the first light-blocking layer 610 may include a valley pattern VP″. The valley pattern VP″ may be defined in the first light-blocking layer 610. The valley pattern VP″ may have a recessed shape (e.g., a substantially recessed shape) in the thickness direction (e.g., z direction) of the first light-blocking layer 610 from an upper surface of the first light-blocking layer 610 in a cross section. In one or more embodiments, the valley pattern VP″ may be in a non-emission area. For example, the valley pattern VP″ may be to overlap the bank layer 280, the first conductive layer 520, and the second conductive layer 540. The valley pattern VP″ may be between adjacent middle openings MOPs from among the plurality of middle openings MOPs.

According to one or more embodiments, as the first light-blocking layer 610 is on the clad layer 550, the valley pattern VP″ may be to expose the upper surface of the clad layer 550. The valley pattern VP″ may be filled with the color filter layer 620 as shown in FIG. 7. In one or more embodiments, the upper surface of the clad layer 550, which is exposed by the valley pattern VP″, may be in direct contact with the color filter layer 620.

For example, the clad layer 550 may be exposed rather than the second conductive layer 540 that is at risk of erosion even if (e.g., when) the valley pattern VP″ is provided, and thus the first light-blocking layer 610 may not need to clad the second conductive layer 540. For example, the first light-blocking layer 610 may not need to cover the end of the second conductive layer 540. In one or more embodiments, the first light-blocking layer 610 may be spaced and/or apart (e.g., spaced apart or separated) from the second conductive layer 540 on a plane. For example, a planar width W1″ of the valley pattern VP″ may be greater than the planar width of the second conductive layer 540.

In one or more embodiments, if (e.g., when) the planar width W1″ of the valley pattern VP″ is wider than the planar width of the second conductive layer 540, the color filter layer 620 within the valley pattern VP″ may be filled relatively more within the valley pattern VP″. For example, as shown in FIG. 7, as the planar area of the valley pattern VP″ increases and the height of the color filter overlapping portion decreases, the height of the second light-blocking layer 630 may also decrease. For example, the height of the second light-blocking layer 630 may be reduced by a thickness H1″ between the upper surface of the first light-blocking layer 610 and an upper surface of the clad layer 550.

In one or more embodiments, if (e.g., when) the height of the second light-blocking layer 630 is low, the second light-blocking layer 630 may have a wide area while ensuring a viewing angle. The planar width W2″ of the second light-blocking layer 630 may increase as the height of the second light-blocking layer 630 decreases, and the reflectivity (e.g., a degree or occurrence of reflectivity) of the display apparatus 1 may decrease or reduce as the planar area of the second light-blocking layer 630 increases. In one or more embodiments, in the display apparatus 1 according to one or more embodiments, the clad layer 550 may be on the second conductive layer 540 and the valley pattern VP″ may be large, and thus the planar area of the second light-blocking layer 630 may be expanded, thereby reducing the reflectivity (a degree or occurrence of reflectivity) and efficiently or suitably improving or enhancing the display quality and visibility (e.g., a degree of visibility) of the display apparatus 1.

According to one or more embodiments, a display apparatus having improved or enhanced display quality may be provided. These embodiments are examples, and the present disclosure is not limited thereto, and the present disclosure is defined by the scope of the appended claims and equivalents thereof.

The display apparatus according to the embodiment may be applied to various electronic apparatuses. An electronic apparatus according to an embodiment of the present disclosure may include the display apparatus (e.g., the display apparatus of FIG. 1) described above, and may further include modules or appratuses having additional functions in addition to the display apparatus.

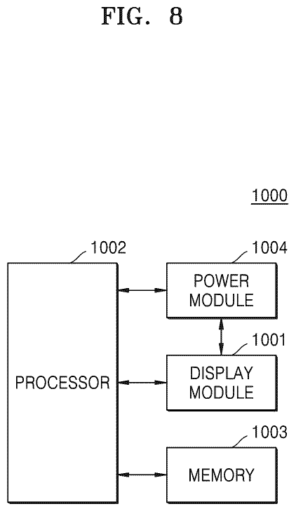

FIG. 8 is a block diagram of an electronic apparatus according to one or more embodiments.

Referring to FIG. 8, an electronic apparatus 1000 according to an embodiment may include a display module 1001, a processor 1002, a memory 1003, and a power module 1004.

The processor 1002 may include at least one of a central processing unit (CPU), an application processor (AP), a graphic processing unit (GPU), a communication processor (CP), an image signal processor (ISP), and a controller.

The memory 1003 may store data information necessary for the operation of the processor 1002 or the display module 1001. When the processor 1002 executes an application stored in the memory 1003, an image data signal and/or an input control signal may be transmitted to the display module 1001, and the display module 1001 may process a signal received and output image information through a display screen.

The power module 1004 may include a power supply module such as a power adapter or a battery device, and a power conversion module that converts the power supplied by the power supply module to generate power necessary for the operation of the electronic apparatus 1000.

At least one of the components of the electronic apparatus 1000 described above may be included in the display apparatus according to the embodiments described above. In addition, a part among the individual modules functionally included in one module may be included in the display apparatus, and another part may be provided separately from the display apparatus. For example, the display apparatus may include the display module 1001, and the processor 1002, the memory 1003, and the power module 1004 may be provided in the form of other apparatuses within the electronic apparatus 1000 except for the display apparatus.

In an embodiment, the display module 1001 included in the display apparatus may drive based on the image data signal and the input control signal received from the processor 1002.

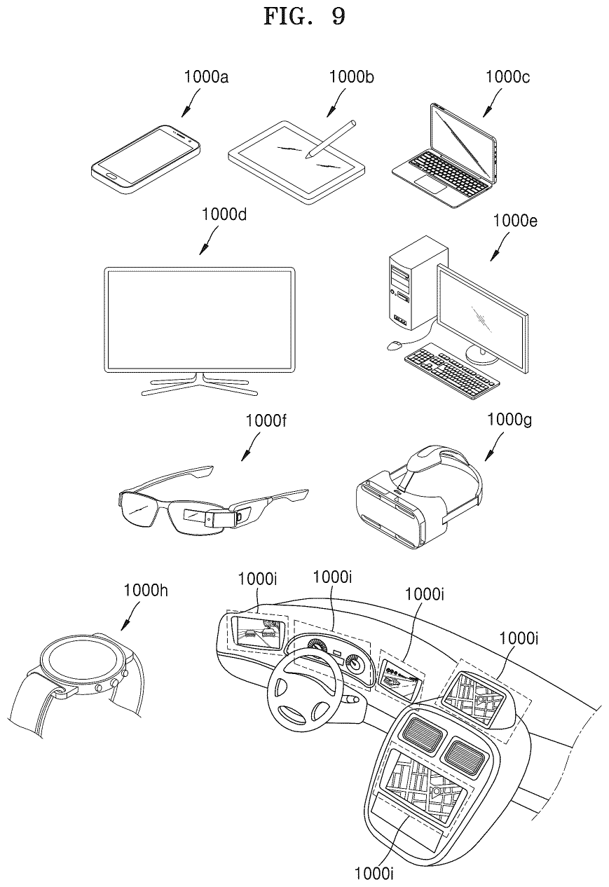

FIG. 9 is schematic diagrams of electronic apparatuses according to various embodiments.

Referring to FIG. 9, various electronic apparatuses to which display apparatuses according to embodiments are applied may include not only image display electronic apparatuses such as a smart phone 1000a, a tablet PC 1000b, a laptop 1000c, a TV 1000d, and a desk monitor 1000e, but also a wearable electronic device including display modules such as smart glasses 1000f, a head mounted display 1000g, and a smart watch 1000h, and a vehicle electronic device 1000i including a dashboard, a center fascia, and display modules such as a CID (Center Information Display) and a room mirror display disposed in the dashboard.

While the subject matter of the present disclosure has been described with reference to certain embodiments illustrated in the drawings, these embodiments are only examples, and those skilled in the art will understand that one or more suitable modifications and equivalent other embodiments are possible therefrom. Therefore, the true technical scope of the disclosure should be determined by the technical spirit of the appended claims and equivalents thereof.

It should be understood that embodiments described herein should be considered in a descriptive sense only and not for purposes of limitation. Descriptions of features or aspects within each embodiment should typically be considered as available for other similar features or aspects in other embodiments. While the subject matter of the present disclosure has been described with reference to the figures, it will be understood by those of ordinary skill in the art that one or more suitable changes in form and more details may be made therein without departing from the spirit and scope as defined by the following claims and equivalents thereof.

What is claimed is:

1. A display apparatus, comprising:
a substrate;
a display element layer on the substrate, wherein the display element layer comprises a plurality of light-emitting devices and a bank layer comprising a lower opening to define respective emission areas of the plurality of light-emitting devices;
an input detection layer on the display element layer; and
a light control layer on the input detection layer,
wherein the light control layer comprises:
a first light-blocking layer comprising a middle opening that is to at least partially overlap the lower opening;
a color filter layer to fill the middle opening, wherein the color filter layer is on the first light-blocking layer; and
a second light-blocking layer on the color filter layer, wherein the second light-blocking layer comprises an upper opening that is to at least partially overlap the middle opening, and
the first light-blocking layer further comprises a valley pattern to overlap the bank layer.

2. The display apparatus as claimed in claim 1, wherein the input detection layer comprises:
a touch insulating layer on the display element layer; and
a conductive layer on the touch insulating layer, and
the valley pattern is to expose therethrough an upper surface of the conductive layer.

3. The display apparatus as claimed in claim 2, wherein the first light-blocking layer is to cover an end of the conductive layer.

4. The display apparatus as claimed in claim 2, wherein a planar width of the valley pattern is less than a planar width of the conductive layer.

5. The display apparatus as claimed in claim 2, wherein the plurality of light-emitting devices comprise a first light-emitting device and a second light-emitting device that are to emit light of different colors and are adjacent to each other, and
the color filter layer comprises a first color filter corresponding to the first light-emitting device and a second color filter corresponding to the second light-emitting device.

6. The display apparatus as claimed in claim 5, wherein the first color filter and the second color filter are to overlap each other at least partially in a plane within the valley pattern.

7. The display apparatus as claimed in claim 5, wherein the valley pattern is filled with the color filter layer.

8. The display apparatus as claimed in claim 7, wherein the upper surface of the conductive layer, exposed by the valley pattern, is in direct contact with the color filter layer.

9. The display apparatus as claimed in claim 5, wherein the first color filter and the second color filter are spaced apart from each other on a plane within the valley pattern.

10. The display apparatus as claimed in claim 9, wherein the second light-blocking layer is between the first color filter and the second color filter, which are spaced apart from each other.

11. The display apparatus as claimed in claim 5, wherein the valley pattern is filled with the color filter layer and the second light-blocking layer.

12. The display apparatus as claimed in claim 11, wherein the upper surface of the conductive layer, exposed by the valley pattern, is in direct contact with the color filter layer and the second light-blocking layer.

13. The display apparatus as claimed in claim 1, wherein the input detection layer comprises:
a touch insulating layer on the display element layer;
a conductive layer on the touch insulating layer; and
a clad layer on the conductive layer, and
the valley pattern is to expose therethrough an upper surface of the clad layer.

14. The display apparatus as claimed in claim 13, wherein the first light-blocking layer is spaced apart from the conductive layer on a plane within the valley pattern.

15. The display apparatus as claimed in claim 13, wherein a planar width of the valley pattern is greater than a planar width of the conductive layer.

16. The display apparatus as claimed in claim 13, wherein the upper surface of the clad layer is in direct contact with the color filter layer within the valley pattern.

17. The display apparatus as claimed in claim 1, further comprising an encapsulation layer between the display element layer and the input detection layer.

18. A display apparatus, comprising:
a substrate;
a display element layer on the substrate, wherein the display element layer comprises a first light-emitting device and a second light-emitting device that are to emit light of different colors and are adjacent to each other;
a first light-blocking layer on the display element layer, wherein the first light-blocking layer comprises a first opening corresponding to the first light-emitting device and a second opening corresponding to the second light-emitting device;
a color filter layer on the first light-blocking layer, wherein the color filter layer comprises a first color filter to fill the first opening and a second color filter to fill the second opening; and
a second light-blocking layer on the color filter layer,
wherein the first light-blocking layer further comprises a valley pattern between the first opening and the second opening.

19. The display apparatus as claimed in claim 18, further comprising an input detection layer between the display element layer and the first light-blocking layer,
wherein the input detection layer comprises a touch insulating layer on the display element layer and a conductive layer on the touch insulating layer.

20. The display apparatus as claimed in claim 19, wherein the valley pattern is to expose therethrough an upper surface of the conductive layer, and
the first light-blocking layer is to cover an end of the conductive layer.

21. The display apparatus as claimed in claim 20, wherein a planar width of the valley pattern is less than a planar width of the conductive layer.

22. The display apparatus as claimed in claim 20, wherein the first color filter and the second color filter are to overlap each other at least partially in a plane within the valley pattern.

23. The display apparatus as claimed in claim 20, wherein the first color filter and the second color filter are spaced apart from each other on a plane within the valley pattern.

24. The display apparatus as claimed in claim 19, wherein the input detection layer further comprises a clad layer on the conductive layer, and
the valley pattern is to expose therethrough an upper surface of the clad layer.

25. The display apparatus as claimed in claim 24, wherein a planar width of the valley pattern is greater than a planar width of the conductive layer.

26. An electronic device comprising a display apparatus comprising:
a substrate;
a display element layer on the substrate, wherein the display element layer comprises a plurality of light-emitting devices and a bank layer comprising a lower opening to define respective emission areas of the plurality of light-emitting devices;
an input detection layer on the display element layer; and
a light control layer on the input detection layer,
wherein the light control layer comprises:
a first light-blocking layer comprising a middle opening that is to at least partially overlap the lower opening;
a color filter layer to fill the middle opening, wherein the color filter layer is on the first light-blocking layer; and
a second light-blocking layer on the color filter layer, wherein the second light-blocking layer comprises an upper opening that is to at least partially overlap the middle opening, and
the first light-blocking layer comprises a valley pattern to overlap the bank layer.

27. The electronic device as claimed in claim 26, further comprising:
a display module;
a processor;
a power module; and
a memory,
wherein the display apparatus includes one of the display module, the processor, the power module, or the memory.
